(19) United States
(12) Patent Application Publication
(10) Pub. No.: US 2003/0068898 A1
(43) Pub. Date: Apr. 10, 2003

(54) Dry etching method for manufacturing processes of semiconductor devices

(76) Inventors: Chun-Hung Lee, Taoyuan (TW); Shiuh-Sheng Yu, Keelung (TW); Ming-Chung Liang, Pingtung (TW)

Correspondence Address: POWELL, GOLDSTEIN,, FRAZER & MURPHY LLP, P.O. BOX 97223, WASHINGTON, DC, 20090-7223, US

(21) Appl. No.: 09/973,926

(22) Filed: Oct. 10, 2001

(51) Int. Cl. H01L 21/302; H01L 21/461

(52) U.S. Cl. 438/712; 438/706

(57) ABSTRACT

A method of etching that can increase the etching selectivity between the dielectric material and silicon in a polysilicon etching apparatus is disclosed. The present invention is a dry etching method, and the gas recipe of the polysilicon plasma etching apparatus is adjusted to serve carbon tetrafluoride (CF₄)/fluoromethane (CHₓF_{y}; x=2, y=2 or x=1, y=3)/Oxygen (O₂) as the reactive gas. Therefore, the dielectric material layer and the polysilicon layer both can be etched in a polysilicon plasma etching apparatus, and the etching selectivity between the dielectric material layer and silicon can be enhanced greatly, so that a straight etching profile and a stable chamber environment can be obtained.

### FIELD OF THE INVENTION

The present invention relates to a method of etching, and more particularly, to a dry etching method that uses carbon tetrafluoride (CF₄)/fluoromethane (CHₓF_{y}; x=2, y=2 or x=1, y=3)/Oxygen (O₂) as the reactive gas.

### BACKGROUND OF THE INVENTION

Generally, the so-called integrated circuit is an electrical technology, which manufactures the components of electrical devices, such as capacitor, resistor, or switch, by using the semiconductor materials, such as silicon or gallium arsenide (GaAs), and reduces the volume and weight of the electrical devices with the technique of deposition, etching and photolithography, etc.

After a series of deposition, several films of different materials are formed to manufacture an electrical device. Then, a pattern having the features of circuits or device is replicated onto a photoresist by a photolithographic process, and is transferred to a film by an etching process so that the desired features of circuits or device are formed on the film. With the coming of the ultra large scale integration (ULSI) era, the etching process plays an increasingly important role on manufacturing the features of sub-half micrometer devices.

Etching process primarily includes a wet etching method and a dry etching method. As the design and manufacture of the semiconductor device has been becoming more delicate and precise, the isotropic wet etching method can not satisfy the requirement of processing precision gradually, and thus the anisotropic dry etching method has been turning to be the mainstream for manufacturing processes. Dry etching method comprises plasma etching method, reactive ion etching (RIE) method, sputtering etching method, ion beam etching method, and reactive ion beam etching method, etc., wherein the plasma etching method and reactive ion etching method are the most popularly-used etching methods in the current semiconductor industry.

In the plasma etching method, plasma is used to dissociate the reactive gas molecules, and the ions, radicals, and atoms produced after the dissociation of reactive gas molecules react chemically with the film molecules exposed to plasma, and volatile products are thus formed. The volatile products are then drawn out the chamber by a vacuum system. Since the plasma etching method is mainly to utilize the chemical reaction between the ions, radicals, and atoms that produced by exciting the reactive gas with plasma and the film molecules, to etch the film, the etching selectivity of the plasma etching method is better than that of the common dry etching methods.

The technique of the reactive ion etching method is similar to that of the plasma etching method, wherein both of them use plasma to dissociate the reactive gas molecules. Ions, radicals, and atoms produced by dissociating the reactive gas molecules are reacted with the film molecules exposed to plasma, so as to etch the film. But there is a difference between these two methods, and the difference is that the ion bombardment intensity in the reactive ion etching method is greater than in that in the plasma etching method. Therefore, in the reactive ion etching method, the etching is performed not only by the chemical reaction between the ions dissociated from the reactive gas and the film molecules, but also by the ion bombardment to the film, so the etching rate of the reactive ion etching method is greater than that of the plasma etching method.

At present, the quality of the dry etching method can be judged from the etching selectivity, etching rate, and etching uniformity, etc. The better etching selectivity represents that the etching process is almost performed on the desired material layer, and the larger etching rate represents that the time-consumption of the etching process is reduced, and further the better etching uniformity represents the increase of the wafer quality, i.e. the increase of the process yield.

### SUMMARY OF THE INVENTION

According to the background of the invention decreased above, the preferred etching method has the features of larger etching rate, better etching selectivity, and better etching uniformity, and the quality of the etching method has great influence on the wafer quality. Therefore, it is an important study direction to improve the etching process quality so as to enhance the semiconductor process yield.

Accordingly, one of the major objects of the present invention is to provide a dry etching method for manufacturing processes of semiconductor devices, and the dry etching method of the present invention is to use carbon tetrafluoride/fluoromethane (CHₓF_{y}; x=2, y=2 or x=1, y=3)/Oxygen (O₂) or inert gas, such as argon (Ar) or helium (He), as the reactive gas for a polysilicon plasma etching apparatus. Since fluoromethane (CHₓF_{y}; x=2, y=2 or x=1, y=3) has better etching selectivity between dielectric material and silicon or polysilicon, the etching selectivity between dielectric material and silicon/polysilicon for carbon tetrafluoride can be enhanced. Oxygen has the characteristic of decreasing the deposition of polymer to obtain a straight etching profile and also maintain the stability of chamber environment.

Another object of the present invention is to provide a dry etching method for manufacturing processes of semiconductor devices, wherein the reactive gas of the present invention is a mixture of carbon tetrafluoride/fluoromethane (CHₓF_{y}; x=2, y=2 or x=1, y=3)/Oxygen (O₂) or inert gas. Since both polysilicon layer and dielectric material layer can be etched in a polysilicon plasma etching apparatus, with the omission of the step of changing chamber, the process time is decreased, and the particle contamination on the chamber and substrate resulted from changing chamber is reduced, and thereby the process yield is enhanced.

According to the aforementioned objects, the present invention provides a dry etching method for manufacturing processes of semiconductor devices, comprising: providing a wafer, and the wafer has a dielectric material layer and a silicon material layer formed thereon; providing a plurality of accelerated electrons; providing a reactive gas, wherein the reactive gas comprises carbon tetrafluoride (CF₄), fluoromethane (CHₓF_{y}; x=2, y=2 or x=1, y=3), and oxygen (O₂), and the reactive gas collides with the accelerated electrons to produce a plurality of ions, a plurality of radicals, and a plurality of atoms; and etching the dielectric material layer and the silicon material layer with the use of the ions, the radicals, and the atoms. In a polysilicon etching apparatus, etching is performed by using fluoromethane (CHₓF_{y}; x=2, y=2 or x=1, y=3) as the reactive gas. Since fluoromethane (CHₓF_{y}; x=2, y=2 or x=1, y=3) has better etching rate on dielectric material, such as silicon nitride (Si₃N₄), silicon-oxy-nitride (SiON), and silicon dioxide (SiO₂), etc., and lower etching rate on silicon, the etching selectivity between the dielectric material and silicon/polysilicon for carbon tetrafluoride can be raised to approximately greater than 3. The use of fluoromethane (CHₓF_{y}; x=2, y=2 or x=1, y=3) results in polymer chemical product in the chamber, and the polymer is easily to be deposited on the chamber wall, which would cause the instability of chamber environment. However, with the addition of oxygen with suitable proportion, the phenomenon of polymer deposition can be reduced. Therefore, the application of the present invention not only can enhance the etching selectivity of the dielectric material to silicon or polysilicon in a polysilicon plasma etching chamber, whereby the desired etched outlook is obtained, but also can etch the dielectric material layer and polysilicon layer in a polysilicon plasma etching apparatus, whereby a stable etching rate is further obtained with reducing the time-consumption of the etching process, and maintaining the stability of chamber environment.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic view showing a plasma etching apparatus in accordance with a preferred embodiment of the present invention;

FIG. 2 is a schematic view showing a reactive ion etching apparatus in accordance with a preferred embodiment of the present invention; and

FIG. 3 is a schematic view showing a high density plasma (HDP) etching apparatus in accordance with a preferred embodiment of the present invention.

### DETAILED DESCRIPTION OF THE PREFERRED EMBODIMENT

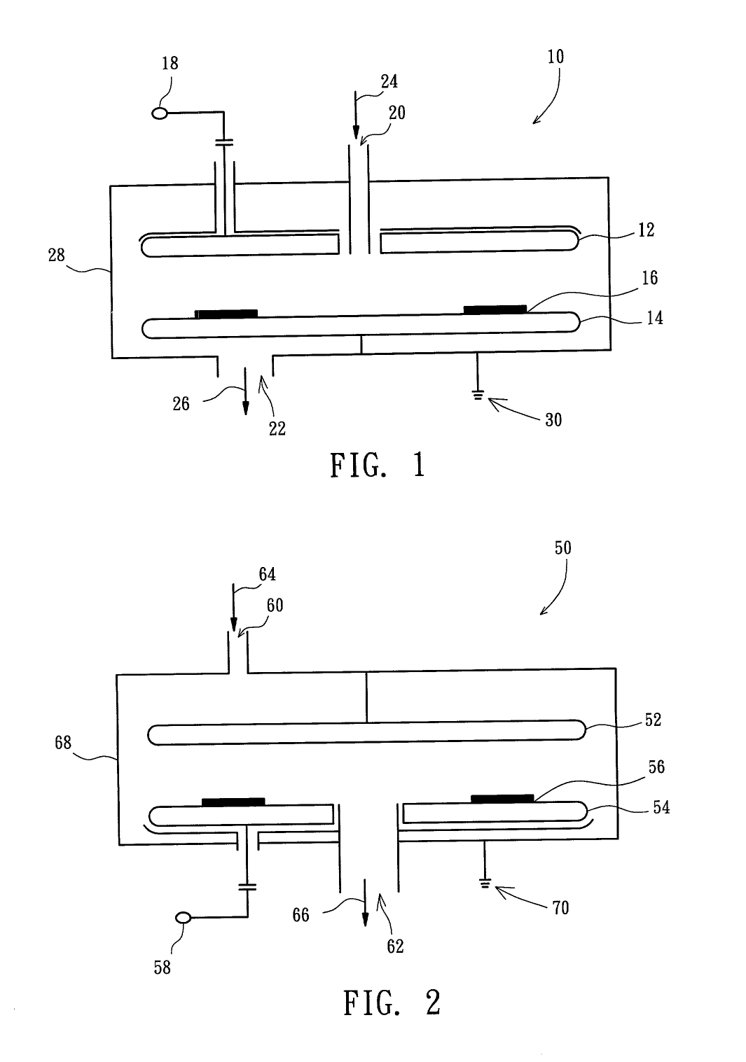

Referring to FIG. 1, FIG. 1 shows a schematic view of a plasma etching apparatus in accordance with a preferred embodiment of the present invention. Plasma etching apparatus 10 is a parallel plate type dry etching apparatus, and chamber 28 comprises a pair of opposite parallel electrode plates, i.e. upper electrode plate 12 and lower electrode plate 14, wherein the upper electrode plate 12 is connected to radio frequency (RF) power 18 and the other parts of the chamber is connected to ground 30, and a wafer 16 to be etched is put on the lower electrode plate 14. Furthermore, a dielectric material layer and a silicon material layer have been formed on the wafer 16, wherein the composition of dielectric material layer can be silicon nitride (Si₃N₄), silicon-oxy-nitride (SiON), silicon dioxide (SiO₂) or combination thereof, etc., and is not limited to a layer of single material, and the composition of silicon material layer can be single crystal silicon, poly-crystal silicon, or amorphous silicon, etc. Besides, the dielectric material layer and the silicon material layer can be formed by stacking in the form of oxide/nitride/oxide (ONO)/polysilicon, silicon-oxy-nitride/nitride/oxide/silicon substrate, or silicon-oxy-nitride/nitride/polysilicon, etc.

During the etching step using a plasma etching apparatus 10, reactive gas 24 is first induced from a gas inlet 20 on the top of chamber 28, wherein the reactive gas 24 is composed of carbon tetrafluoride/fluoromethane (CHₓF_{y}; x=2, y=2 or x=1, y=3)/Oxygen or added inert gas, and the gas flow ratio of fluoromethane (CHₓF_{y}; x=2, y=2 or x=1, y=3) to carbon tetrafluoride is approximately greater than 0.2, and the gas flow ratio of Oxygen to fluoromethane (CHₓF_{y}; x=2, y=2 or x=1, y=3) is approximately greater than 0.04. The electrons are accelerated by the electric field generated from radio frequency power 18, and the electrons with kinetic energy are collided with the reactive gas 24 whereby the reactive gas 24 is dissociated into ions, radicals, and atoms, etc. The chemical property of the dissociated ions, radicals, and atoms is quite active, which is very susceptible to the reaction with the molecules of wafer 16, so that the wafer 16 is etched and volatile waste gas 26 is formed, wherein the volatile waste gas 26 is exhausted through a gas outlet 22. In addition, after plasma is produced, the potential difference between plasma and the upper electrode plate 12 moves the positive-charged particles toward the upper electrode plate 12. Hence, the ion bombardment intensity is relatively less for the wafer 16 on the lower electrode plate 14.

Referring to FIG. 2, FIG. 2 shows a schematic view of a reactive ion etching apparatus in accordance with a preferred embodiment of the present invention. The reactive ion etching apparatus 50 is also a parallel-plate type dry etching apparatus, and chamber 68 comprises the opposite and paralleled upper electrode plate 52 and lower electrode plate 54, wherein the lower electrode plate 54 is connected to radio frequency power 58 and wafer 56 is located thereon, and the other parts of chamber are connected to ground 70.

While an etching step is performed by using the reactive ion etching apparatus 50, the reactive gas 64 is first induced into the chamber 68 through the upper gas inlet 60, wherein the reactive gas 64 comprises carbon tetrafluoride/fluoromethane (CHₓF_{y}; x=2, y=2 or x=1, y=3)/Oxygen or added inert gas, and the gas flow ratio of fluoromethane (CHₓF_{y}; x=2, y=2 or x=1, y=3) to carbon tetrafluoride is approximately greater than 0.2, and the gas flow ratio of Oxygen to fluoromethane (CHₓF_{y}; x=2, y=2 or x=1, y=3) is approximately greater than 0.04. Then, the electrons are accelerated by the electric field generated from radio frequency power 58, so that the electrons with kinetic energy are produced. When these energized electrons are collided with reactive gas 64, the molecules of the reactive gas 64 are dissociated into ions, radicals, and atoms, etc. The chemical property of ions, radicals, and atoms is very active, and is easily to result in the chemical reaction with the molecules of the wafer 56. Wafer 56 is etched by said chemical reaction, and volatile waste gas 66 is produced and thereafter is exhausted through a gas outlet 62. Because radio frequency power 58 of the reactive ion etching apparatus 50 is connected to the lower electrode plate 54, after plasma is produced, the potential difference between plasma and the lower electrode plate 54 moves the positive-charged particles toward the lower electrode plate 54. Therefore, except the aforementioned etching reaction, the etching functions also include the ion bombardment produced by the ions with high energy on the wafer 16, whereby the desired portion of wafer 56 for etching is removed by the momentum transfer caused by the ion bombardment By comparison, the etching rate of reactive ion etching method is better than that of plasma etching method.

The etching mechanism of the reactive ion etching method and that of the plasma etching method are very similar, except the different electrode plates to which the radio frequency power is connected. Said difference results in the difference of plasma ion bombardment intensity to the wafer, and hence the etching rate and the anisotropic of the reactive ion etching method are both better than those the plasma etching method.

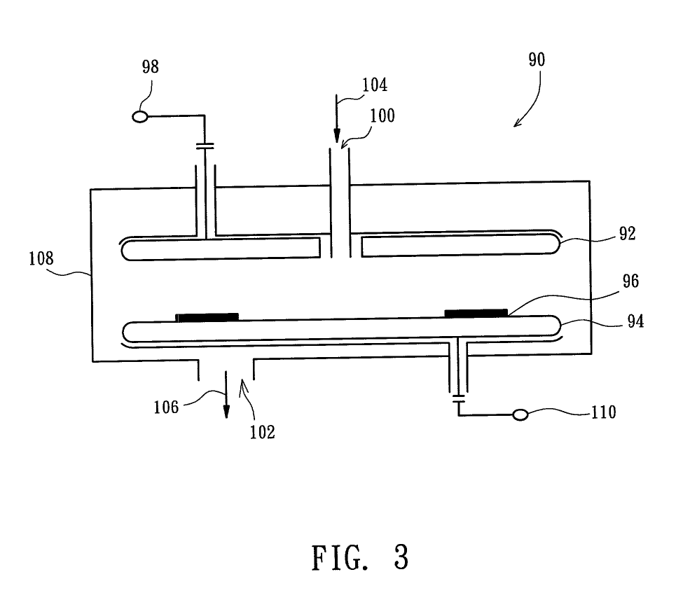

Referring to FIG. 3, FIG. 3 shows a schematic view of a HDP etching apparatus in accordance with a preferred embodiment of the present invention. HDP etching apparatus 90 is also a parallel plate type dry etching apparatus, and chamber 108 comprises a pair of opposite parallel electrode plates, i.e. upper electrode plate 92 and lower electrode plate 94, wherein the upper electrode plate 92 is connected to transformer coupled plasma (TCP) power 98 and the lower electrode plate 94 is connected to RF bias power 110, and a wafer 96 to be etched is put on the lower electrode plate 94, and the TCP power 98 can be replaced with a RF power.

While an etching step is performed by using a HDP etching apparatus 90, reactive gas 104 is first induced from a gas inlet 100 on the top of chamber 108, wherein the reactive gas 104 is composed of carbon tetrafluoride/fluoromethane (CHₓF_{y}; x=2, y=2 or x=1, y=3)/Oxygen or added inert gas, and the gas flow ratio of fluoromethane (CHₓF_{y}; x=2, y=2 or x=1, y=3) to carbon tetrafluoride is approximately greater than 0.2, and the gas flow ratio of Oxygen to fluoromethane (CHₓF_{y}; x=2, y=2 or x=1, y=3) is approximately greater than 0.04. The electrons are accelerated by the electric field generated from TCP power 98, and the electrons with kinetic energy are collided with the reactive gas 104 whereby the reactive gas 104 is dissociated into ions, radicals, and atoms, etc. The chemical property of the dissociated ions, radicals, and atoms is quite active, which is very susceptible to the reaction with the molecules of wafer 96, so that the wafer 96 is etched and volatile waste gas 106 is formed, wherein the volatile waste gas 106 is exhausted through a gas outlet 102. Because the direction of the accelerated electric field generated from TCP power 98 is a circular closed curve, and the accelerated direction of the electrons is parallel to the tangent direction of the wafer surface, hence the wafer 96 is not damaged.

The etching method of the present invention can be applied to a polysilicon etching apparatus which performs etching by plasma directly contacting with the wafer. The feature of the present invention is to use carbon tetrafluoride/fluoromethane (CHₓF_{y}; x=2, y=2 or x=1, y=3)/Oxygen or added inert gas as reactive gas to etch the dielectric material layers, such as silicon nitride, silicon dioxide, and silicon-oxy-nitride, etc., and silicon material layers, such as single crystal silicon, poly-crystal silicon, and amorphous silicon, etc., on the wafer, wherein the gas flow ratio of fluoromethane (CHₓF_{y}; x=2, y=2 or x=1, y=3) to carbon tetrafluoride is approximately greater than 0.2, and the gas flow ratio of Oxygen to fluoromethane (CHₓF_{y}; x=2, y=2 or x=1, y=3) is approximately greater than 0.04. Since fluoromethane (CHₓF_{y}; x=2, y=2 or x=1, y=3) has better etching selectivity between the dielectric material and silicon/polysilicon in a polysilicon etching apparatus, the etching selectivity between the dielectric material and silicon/polysilicon for carbon tetrafluoride can be enhanced to approximately greater than 3. As to the conventional method that uses carbon tetrafluoride/argon or carbon tetrafluoride/helium as the process gas to etch the dielectric material, its etching selectivity between the dielectric material and silicon/polysilicon is approximately less than 1.5. Accordingly, the etching selectivity of the present invention between the dielectric material and silicon/polysilicon is better than that of the conventional method. In addition, oxygen is used to decrease the polymer deposition resulted from fluoromethane (CHₓF_{y}; x=2, y=2 or x=1, y=3), and thereby the stability of chamber environment can be maintained. Also, with the use of a mixture of carbon tetrafluoride/fluoromethane (CHₓF_{y}; x=2, y=2 or x=1, y=3)/Oxygen as the reactive gas, the polysilicon plasma etching apparatus can be used to etch not only the polysilicon material layer but also the dielectric material layer.

The advantage of the present invention is to provide a dry etching method for manufacturing processes of semiconductor devices, and the dry etching method of the present invention is applied in a polysilicon etching apparatus, wherein the reactive gas comprises carbon tetrafluoride, fluoromethane (CHₓF_{y}; x=2, y=2 or x=1, y=3), or Oxygen added inert gas. Because fluoromethane (CHₓF_{y}; x=2, y=2 or x=1, y=3) has the characteristic of high etching rate for the dielectric material layer and low etching rate for silicon/polysilicon in a polysilicon etching apparatus, and oxygen can reduce the polymer deposited phenomenon resulted from fluoromethane (CHₓF_{y}; x=2, y=2 or x=1, y=3), with the application of the present invention, not only the etching selectivity between the dielectric material layer and silicon/polysilicon for the carbon tetrafluoride can be increased up to about 3 and thereby a straight etching profile is obtained, but also the stability of chamber environment can be maintained and thereby a stable etching rate is obtained. Furthermore, both polysilicon and dielectric material layer can be etched in the same polysilicon etching apparatus, so that the time and manpower for changing chamber can be saved, and the particles contamination resulted from changing chamber can be avoided.

As is understood by a person skilled in the art, the foregoing preferred embodiments of the present invention are illustrations of the present invention rather than limitations of the present invention. It is intended to cover various modifications and similar arrangements included within the spirit and scope of the appended claims, the scope of which should be accorded the broadest interpretation so as to encompass all such modifications and similar structure.

What is claimed is:

1. A dry etching method for manufacturing processes of semiconductor devices, comprising:
providing a wafer, and the wafer has a dielectric material layer and a silicon material layer formed thereon;
providing a plurality of accelerated electrons;
providing a reactive gas, wherein the reactive gas comprises carbon tetrafluoride (CF₄), fluoromethane (CHₓF_{y}; x=2, y=2 or x=1, y=3), and oxygen (O₂), and the reactive gas collides with the accelerated electrons to produce a plurality of ions, a plurality of radicals, and a plurality of atoms; and
etching the dielectric material layer and the silicon material layer with the use of the ions, the radicals, and the atoms.

2. The method according to claim 1, wherein the wafer is located in a polysilicon etching apparatus.

3. The method according to claim 2, wherein the polysilicon etching apparatus uses plasma to perform an etching step.

4. The method according to claim 1, wherein the accelerated electrons are provided by a radio frequency (RF) power.

5. The method according to claim 1, wherein the accelerated electrons are provided by a TCP power.

6. The method according to claim 1, wherein the dielectric material layer is selected from a group composed of silicon nitride (Si₃N₄), silicon-oxy-nitride (SiON), and silicon dioxide (SiO₂).

7. The method according to claim 1, wherein the silicon material layer is selected from a group composed of single crystal silicon, poly-crystal silicon, and amorphous silicon.

8. The method according to claim 1, wherein a flow ratio of the fluoromethane to the carbon tetrafluoride of the reactive gas is approximately greater than 0.2.

9. The method according to claim 1, wherein a flow ratio of the oxygen to the fluoromethane of the reactive gas is almost approximately than 0.04.

10. The method according to claim 1, wherein the step of etching the dielectric material layer and the silicon material layer has an etching selectivity approximately greater than 3.

11. The method according to claim 1, wherein the reactive gas further comprises an inert gas.

12. The method according to claim 11, wherein the inert gas is argon (Ar).

13. The method according to claim 11, wherein the inert gas is helium (He).

14. A dry etching method for manufacturing processes of semiconductor devices comprises providing a reactive gas for a polysilicon etching apparatus to perform an etching step for a wafer, wherein the reactive gas comprises carbon tetrafluoride, fluoromethane (CHₓF_{y}; x=2, y=2 or x=1, y=3), oxygen, and inert gas, and the wafer has at least one dielectric material layer and a silicon material layer formed thereon.

15. The method according to claim 14, wherein the etching step is performed by using a plasma.

16. The method according to claim 14, wherein a flow ratio of the fluoromethane to the carbon tetrafluoride of the reactive gas is approximately greater than 0.2.

17. The method according to claim 14, wherein a flow ratio of the oxygen to the fluoromethane of the reactive gas is almost approximately than 0.04.

18. The method according to claim 14, wherein the at least one dielectric material layer is selected from a group composed of silicon nitride, silicon-oxy-nitride, and silicon dioxide.

19. The method according to claim 14, wherein the silicon material layer is selected from a group composed of single crystal silicon, poly-crystal silicon, and amorphous silicon.

20. The method according to claim 14, wherein the etching step has an etching selectivity for the at least one dielectric material layer to the silicon material layer approximately greater than 3.

21. The method according to claim 14, wherein the inert gas is argon.

22. The method according to claim 14, wherein the inert gas is helium.

23. A dry etching method for manufacturing processes of semiconductor devices, comprising:
providing a polysilicon etching apparatus having a chamber, wherein the polysilicon etching apparatus is connected to a power, and the polysilicon etching apparatus is used to etch at least one wafer in the chamber, and the at least one wafer has at least one dielectric material layer and a silicon material layer formed thereon;
turning on the power to generate a plurality of accelerated electrons;
providing a reactive gas, wherein the reactive gas comprises carbon tetrafluoride, fluoromethane (CHₓF_{y}; x=2, y=2 or x=1, y=3), and oxygen, and a flow ratio of the fluoromethane to the carbon tetrafluoride of the reactive gas is approximately greater than 0.2, and a flow ratio of the oxygen to the fluoromethane of the reactive gas is approximately greater than 0.04, and the reactive gas collides with the accelerated electrons to produce a plurality of ions, a plurality of radicals, and a plurality of atoms; and
etching the at least one dielectric material layer and the silicon material layer by the ions, the radicals, and the atoms.

24. The method according to claim 23, wherein the power is a radio frequency power.

25. The method according to claim 23, wherein the at least one dielectric material layer is selected from a group composed of silicon nitride, silicon-oxy-nitride, and silicon dioxide.

26. The method according to claim 23, wherein the silicon material layer is selected from a group composed of single crystal silicon, poly-crystal silicon, and amorphous silicon.

27. The method according to claim 23, wherein the step of etching the at least one dielectric material layer and the silicon material layer has an etching selectivity almost approximately than 3.

28. The method according to claim 21, wherein the reactive gas further comprises argon.

29. The method according to claim 21, wherein the reactive gas further comprises helium.
